(19) United States
(12) Patent Application Publication
(10) Pub. No.: US 2016/0097885 A1
(43) Pub. Date: Apr. 7, 2016

(54) MIRROR SUBSTRATES WITH HIGHLY FINISHABLE CORROSION-RESISTANT COATING

(71) Applicant: Corning Incorporated, Corning, NY (US)

(72) Inventors: Lovell Elgin Comstock, II, Charlestown, NH (US); Joseph Charles Crifasi, Stoddard, NH (US); Brian Paul Roy, Dublin, NH (US); Robin Merchant Walton, Redwood City, CA (US); Leonard Gerard Wamboldt, Sunderland, MA (US); Kenneth Smith Woodard, New Boston, NH (US)

(21) Appl. No.: 14/865,380

(22) Filed: Sep. 25, 2015

Related U.S. Application Data
(60) Provisional application No. 62/059,469, filed on Oct. 3, 2014.

(51) Int. Cl. G02B 5/08; B24B 13/00; C23C 14/35; C23C 14/58; G02B 1/14; G02B 1/12

(52) U.S. Cl. CPC G02B 5/0891; G02B 5/08; G02B 1/14; G02B 1/12; C23C 14/35; C23C 14/588; B24B 13/0018

(57) ABSTRACT

The disclosure is directed to optical elements including a performance-enhancing coating on the surface of a metal or ceramic substrate and to methods for making the optical elements. The optical elements are suitable for use in harsh environments, including salt fog and high humidity environments. The performance-enhancing coating and substrate have similar thermal expansion properties and the performance-enhancing coating has a diamond-turned surface. The performance-enhancing coating may also be polished with a solution of colloidal silica in glycol to an RMS surface roughness less than 30 Å.

### RELATED APPLICATION INFORMATION

This application claims the benefit of priority under 35 U.S.C. §119 of U.S. Provisional Application Ser. No. 62/059,469 filed on Oct. 3, 2014 the content of which is relied upon and incorporated herein by reference in its entirety.

### FIELD

This disclosure is directed to highly finishable optical mirrors fabricated from metal or ceramic substrates for use in corrosive environments, and to a method for treating metal or ceramic substrates to improve finishability and corrosion resistance in harsh environments.

### BACKGROUND

Optical systems are widely used for sensing, detection, and light sources. Common applications include used remote sensing for homeland security, aerospace and defense, laser systems, solar power concentrators, metrology, and optical scanning systems. Optical systems are needed for operation over a variety of wavelengths, including visible (VIS) through long wave infra-red (LWIR) wavelengths. As the utility and sensitivity of optical systems improves, it is becoming desirable to deploy them in a wider range of operating environments. In particular, there is a need to develop optical systems with high durability that are capable of operating in harsh environments. Harsh environments include corrosive environments (e.g. salt fog, high alkalinity) and humid environments.

Mirrors are central components of optical systems. Mirrors are typically fabricated from a metal or ceramic substrate with a finely polished surface and/or a reflective coating. A preferred material for mirror substrates is an aluminum alloy, T6 6061-Al (T6 6061-Al), due to its relatively low cost, manufacturability, strength and light weight. T6 6061-Al alloy nominally contains 95.8-98.6 wt % Al, 0.04-0.35 wt % Cr, 0.15-0.4 wt % Cu, 0.8-1.2 wt % Mg, 4-0.6.0 wt % Si, and may additionally contain up to 0.75 wt % Fe, 0.155 wt % Mn, 0.155 wt % Ti, 0.255 wt % Zn, and other residual elements (up to 0.05 wt % of any one residual element, with the collective amount of all other residual elements not exceeding 0.155 wt %).

Analysis of the microstructure of T6 6061-Al alloy reveals the presence of intermetallic particles in the material. The presence of intermetallic particles is believed to be responsible for two significant drawbacks that limit the application of T6 6061-Al alloy. First, the intermetallic particles contribute to roughness on the surface and lead to a decrease in reflected intensity and optical throughput due to scattering losses. The intermetallic particles degrade the quality of the surface and cannot be eliminated by polishing. Second, the intermetallic particles, or the grain boundaries associated with them, constitute sites of high reactivity that make T6 6061-Al alloy susceptible to corrosion.

FIG. 1 shows an SEM image of the surface of an uncoated T6 6061-Al alloy substrate after exposure to a humid salt water environment. The image shows corrosion at the site of an intermetallic particle. Chemical analysis of the corrosion site indicates the presence of a corrosion product that consists primarily of Na, Cl, and O. FIG. 2 shows an SEM image of a coated T6 6061-Al alloy substrate after exposure to a humid salt water environment. The image plane is at the interface of the substrate and the reflective coating. The image shows that corrosion occurs at intermetallic particles of the substrate despite the presence of the reflective coating. Chemical analysis indicates that the corrosion product consists primarily of Na, Cl and O. The corrosion product distorts the reflective coating and causes it to fracture and peel, thus rending the mirror unsuitable for use in the corrosive environment. The corrosion product also leads to surface roughness, increased scattering, decreased optical throughput and a reduced threshold for laser damage.

Electrochemical nickel plating and aluminum plating processes have been developed recently in an effort to improve the durability of mirrors in harsh environments. Nickel-plated finished optics have demonstrated enhanced corrosion resistance when exposed to harsh environments such as salt fog and extended humidity. Plated nickel also provides a homogenous plating surface and can be finished to a surface smoothness in the range of 10-20 Å RMS (root-mean-square). The net effect of the homogeneous plating and the low surface finish is an improvement in enhanced laser damage threshold performance. Unfortunately, due to the thickness of the plated Ni coating in conjunction with the CTE (coefficient of thermal expansion) mismatch between Al mirror substrates (including T6 6061-Al) and the plated Ni coating, the operational temperature range of nickel-plated optics is limited and such optics are unsuitable for mirrors deployed in environments experiencing large operational temperature ranges (e.g. −70° C. to +60° C.), where figure requirements are demanding. Figure requirements include specifications for surface wavefront distortion, surface flatness and/or surface curvature for the mirror.

Aluminum plating of Al and Al alloy substrates can achieve both corrosion resistance and low surface finish (highly smooth, low roughness surface) and offers a better CTE match with T6 6061-Al substrates. As a result, mirrors made by plating T6 6061-Al substrates with aluminum maintain figure specifications over a larger operational temperature range. However, it is often desirable to selectively coat only portions of the optical surface of the mirror substrate while avoiding coating of other locations on the mirror substrate. Since electroplating is a conformal process, the entire mirror substrate is exposed to the plating solution and is subject to plating. To achieve selective area coating of substrates in a plating process, it is necessary to implement masking or other complex processing techniques. Such techniques are often technically challenging, only moderately effective, and add significantly to the cost and time of manufacturing.

Amorphous silicon and nickel-chromium thin films have also been used to achieve low roughness surface finishes on T6 6061-Al and can circumvent concerns over CTE mismatch by maintaining thin film thickness below 1 μm (see, for example, U.S. Pat. No. 6,921,177). However, these coatings have intrinsic stresses that are likely to prevent the use of this technology on mirrors with a high aspect ratio. In addition, the low film thicknesses needed to avoid CTE mismatch problems limits the corrosion resistance properties of the films. While polishing the surface of T6 6061-Al coated with amorphous silicon or nickel-chromium thin films can result in a low surface finish (10 Å RMS roughness), bi-directional reflective distribution function (BRDF) scattering tests indicate that the resulting surface effectively performs as if it had a 60 Å RMS surface finish because the surface peak-to-valley variations remain high as a result of impurities.

There remains a need to develop substrates for mirrors that are capable of deployment in harsh chemical environments over wide ranges of temperature and spectral wavelength.

### SUMMARY

The present description provides an optical element that includes a performance-enhancing coating supported by a substrate and methods for making the optical element. The performance-enhancing coating imparts superior resistance to corrosion to the optical element and is capable of being finished to provide an extremely smooth, low finish surface to minimize distortions of optical signals reflected from the element. The optical element can be safely deployed in operating environments having high humidity and/or corrosive conditions over a wide temperature range without failing or deteriorating.

The optical element includes a substrate. The substrate may be Al, an alloy of Al, Mg, or an alloy of Mg. The alloy of Al may be T6 6061-Al. The substrate may include intermetallic particles. The substrate may be formed from wrought alloy stock, or by direct metal laser sintering (DMLS) or by casting. The substrate may have an aspect ratio of at least 1:1, or at least 2:1, or at least 5:1, or at least 10:1, or at least 20:1.

The optical element includes a performance-enhancing coating on the substrate. The performance-enhancing coating features high finishability and excellent corrosion resistance. The performance-enhancing coating also bridges small surface voids and/or porosity commonly associated with substrates made from DMLS and casting processes. The corrosion resistance of the performance-enhancing coating enables deployment of the element in environments with harsh conditions. Harsh conditions include corrosive conditions, alkaline conditions, and humid conditions. High finishability makes the performance-enhancing coating amenable to finishing processes that provide ultrasmooth, low finish surfaces with low surface roughness.

The performance-enhancing coating may include Al or an alloy of Al. Alloys of Al include alloys of Al with one or more of Sb, Bi, B, Ca, C, Cr, Co, Cu, Ga, In, Fe, Pb, Li, Mg, Ni, Nb, P, Si, V, Zn, and Zr. The performance-enhancing coating may differ in composition from the substrate and may lack intermetallic particles. The performance-enhancing coating may be a layer of a single material or a multilayer stack of two or more materials.

The thickness of the performance-enhancing coating is preferably sufficiently large to permit post-deposition diamond turning without damaging the underlying substrate. The performance-enhancing coating may have a thickness in the range from 30 μm to 300 μm, or in the range from 40 μm to 300 μm, or in the range from 50 μm to 300 μm, or at least 40 μm, or at least 120 μm. The composition of the performance-enhancing coating can be designed to provide an excellent CTE match with the substrate.

The optical element may include an interface layer between the performance-enhancing coating and the substrate. The interface layer may promote adhesion between the performance-enhancing coating and substrate. The interface layer may also insure galvanic compatibility between the performance-enhancing coating and substrate. The interface layer may include one or more of Ni, Cr, NiCr, Ti, Al₂O₃, MgF₂, Bi or Bi₂O₃. In one embodiment, the substrate includes Mg or an alloy of Mg, the coating includes Al or an alloy of Al, and the optical element includes an interface layer between the substrate and performance-enhancing coating, where the interface layer includes a dielectric compound of Mg, such as MgF₂.

The optical element may include a reflective coating on the highly finishable performance-enhancing coating. The reflective coating may be a layer of a single material or a multilayer combination of two or more materials. The reflective coating may include a reflective transition metal layer. The transition metal layer may be metallic, non-ionic, and/or zero valent. The transition metal layer may include one or more elements selected from the group consisting of Ag, Au, Al, Rh, Cu, Pt and Ni. The thickness of the reflective layer may be in the range of 75 nm to 350 nm.

The reflective coating may include one or more layers deposited on the transition metal layer. The overlying layers may perform such functions such as tuning the performance of the optical element or protecting the optical element from harsh environments. The protective layer(s) is the last layer applied and forms the top layer of the reflective coating. The protective layer(s) may have a thickness in the range of 60 nm to 200 nm. The tuning layer is positioned between the protective layer(s) and the performance-enhancing coating. The tuning layer may be positioned between the performance-enhancing coating and the transition metal layer or between the transition metal layer and the protective layer. The tuning layer may have a thickness in the range of 75 nm to 300 nm. Representative materials for the tuning layer include YbF₃, YbFₓO_{y}, YF₃, GdF₃ and Bi₂O₃. Representative materials for the protective layer include YbF₃, YbFₓO_{y}, YF₃ and Si₃N₄. The transition metal layer and tuning layer may be in direct contact or an intervening layer may be present between the transition metal layer and tuning layer. The intervening layer may have a thickness in the range of 5 nm to 20 nm and may include one or more of Nb₂O₅, TiO₂, Ta₂O₅, Bi₂O₃, ZnS and Al₂O₃.

Preparation of the optical element may include treatment of the substrate surface. Treatment of the substrate surface may include heating the substrate surface, polishing the substrate surface, exposing the substrate surface to a plasma or an ion beam, or diamond turning. Treatment may reduce the roughness of the surface of the substrate. The RMS (root-mean-square) roughness of the treated substrate surface may be less than 60 Å, or less than 50 Å, or less than 40 Å.

The performance-enhancing coating may be formed on an untreated or treated surface of the substrate. The performance-enhancing coating may be deposited by sputtering. In one embodiment, the performance-enhancing coating is deposited by plasma ion assisted deposition. The performance-enhancing coating may be densified during deposition to minimize defects. Densification techniques include ion or plasma bombardment of the performance-enhancing coating during deposition, minimization of high angle deposition from the sputtering target (e.g. via source masking), or inclusion of one or more densification layers in the performance-enhancing coating. The densification technique may also smoothen the performance-enhancing coating. In one embodiment, the performance-enhancing coating is deposited by a modified version of plasma ion assisted deposition that includes plasma smoothing. After deposition, the surface of the performance-enhancing coating may be finished to reduce roughness. Finishing may include diamond turning and/or polishing. The finished surface of the performance-enhancing coating may have an RMS roughness less than 40 Å, or less than 30 Å, or less than 20 Å, or less than 15 Å, or less than 10 Å. Finishing may remove periodic structures from the performance-enhancing coating.

Polishing of the substrate or performance-enhancing coating may include applying a polishing formulation that includes colloidal silica. The polishing formulation may be a solution or suspension of colloidal silica in an alcohol. The alcohol may be a glycol, such as ethylene glycol or propylene glycol. The polishing formulation may also include an alumina suspension and/or a surfactant. The polishing solution may have a pH of at least 8.0, or at least 8.5, or between 8.0 and 10.0, or between 8.5 and 9.5, or between 8.75 and 9.25.

The reflective coating may be formed on an unfinished or finished surface of the performance-enhancing coating.

The present description extends to:

A method for treating a substrate comprising:
providing a substrate, said substrate having a surface coated with a performance-enhancing coating, said performance-enhancing coating differing in composition from said substrate and having a thickness in the range from 40 μm to 300 μm;
finishing a surface of said performance-enhancing coating, said finishing including diamond turning said surface of said performance-enhancing coating and polishing said diamond-turned surface of said performance-enhancing coating, said finishing reducing the RMS (root-mean-square) roughness of said surface of said performance-enhancing coating to less than 40 Å.

The present description extends to:

A method for treating a substrate comprising:
providing a substrate, said substrate having a surface coated with a performance-enhancing coating, said performance-enhancing coating differing in composition from said substrate and having a thickness in the range from 40 μm to 300 μm;
finishing a surface of said performance-enhancing coating, said finishing including diamond turning said surface of said performance-enhancing coating and polishing said diamond-turned surface of said performance-enhancing coating, said finishing reducing the RMS (root-mean-square) roughness of said surface of said performance-enhancing coating to less than 25 Å.

The present description extends to:

An optical element comprising:
a substrate;
a performance-enhancing coating on a surface of said substrate, said performance-enhancing protection coating differing in composition from said substrate and having a thickness in the range from 40 μm to 300 μm, said performance-enhancing coating having a surface with an RMS (root-mean-square) roughness of less than 40 Å; and a reflective coating on said surface of said performance-enhancing coating.

### BRIEF DESCRIPTION OF THE DRAWINGS

While the specification concludes with claims particularly pointing out and distinctly claiming the subject matter of the description, it is believed that the specification will be better understood from the following written description when taken in conjunction with the accompanying drawings, wherein:

FIG. 1 shows a secondary electron microscope image of a corrosion site on the surface of a T6 6061-Al substrate.

FIG. 2 shows a secondary electron microscope image of a corrosion site at the interface of a reflective thin film stack and a T6 6061-Al substrate.

FIG. 3 shows an embodiment of an optical element having a substrate, a performance-enhancing coating, and a reflective coating.

FIG. 4 shows an embodiment of an optical element having a substrate, a performance-enhancing coating, a reflective metal layer and one or more tuning layers.

FIG. 5 shows an embodiment of an optical element having a substrate, a performance-enhancing coating, a reflective metal layer, one or more tuning layers, one or more interface layers, and a protective layer.

FIG. 6 shows an embodiment of an optical element having an adhesion layer and a barrier layer between a performance-enhancing coating and a substrate.

FIG. 7 shows an embodiment of an optical element having a performance-enhancing coating that includes multiple layers of a performance-enhancing material and intervening layers of Al₂O₃.

FIG. 8 shows the bidirectional reflective distribution function for two samples of T6 6061-Al substrate material.

FIG. 9 shows the power spectral density function of various samples of uncoated and coated T6 6061-Al alloy substrates.

FIG. 10 shows an SEM image and 3D model of the surface of a performance-enhancing coating on T6 6061-Al substrate.

FIG. 11 shows surface images of a T6 6061-Al substrate with a pure Al performance-enhancing coating at different temperatures.

FIG. 12 shows surface images of a T6 6061-Al substrate without a performance-enhancing coating at different temperatures.

FIG. 13 shows an image of the surface of a high aspect ratio (25:1) T6 6061-Al substrate with a pure Al performance-enhancing coating.

FIG. 14 shows SEM images of surfaces of various samples.

FIG. 15 shows a substrate prepared by the DMLS process.

FIG. 16 shows a surface image of a substrate prepared by the DMLS process.

### DETAILED DESCRIPTION OF THE ILLUSTRATED EMBODIMENTS

In the following description, compositions are reported in units of weight percent (wt %). When quantities are expressed on the basis of a range of values, it is understood that the range is inclusive of endpoints. Relative positional references such as “top”, “above”, “over”, “overlying” and the like are used herein to refer to position relative to a substrate. The top layer of a multilayer stack, for example, is the layer that is most remote (furthest) from the substrate. A layer is above or over another layer if it is positioned further from the substrate. A layer is below or under another layer if it is between the layer and the substrate. A layer is on another layer if it is above the layer. Layers positioned above or below one another may or may not be in direct contact. As used herein, layers are in direct contact if they touch each other. Layers are in indirect contact if one or more intervening layers are present between the layers.

The present description provides an optical element suitable for deployment in harsh environments. Harsh environments include environments with high humidity, high alkalinity, corrosive conditions, and/or extreme temperatures. Salt fog is an example of a harsh condition. Deployment environment subject to high and/or low temperatures, such as a temperature as low as −70° C. or a temperature as high as 60° C., is another example of a harsh condition. The present optical elements are capable of withstanding harsh conditions while maintaining performance without degrading.

The optical element is a reflective element that includes at least a substrate, a performance-enhancing coating, and an optional reflective coating. The performance-enhancing coating is positioned on the substrate or between the substrate and reflective coating. The performance-enhancing coating imparts corrosion resistance to the element and features a highly finishable surface that can be process to a low finish (low roughness). The optical element may optionally include layers between the substrate and the performance-enhancing coating or between the performance-enhancing coating and the reflective coating. Such layers may be referred to herein as interface layers or intervening layers. Interface layers may promote adhesion or provide galvanic compatibility between adjacent layers.

The substrate of the optical element may be a metal, metal alloy, glass, glass ceramic, or ceramic. Representative substrates include Al metal, an alloy of Al, Mg metal, an alloy of Mg, or silica glass. The alloy of Al may include at least 85 wt % Al, or at least 90 wt % Al, or at least 95 wt % Al. A representative alloy of Al is T6 6061-Al. The alloy of Mg may include at least 80 wt % Mg, or at least 85 wt % Mg, or at least 90 wt % Mg. Representative alloys of Mg include AZ80A, AZ31B, and ZK60A. Compositions of these alloys are shown in Table 1 below. The substrate may include intermetallic particles.

TABLE 1
Compositions of Selected Mg Alloy Substrate Materials

| Element | AZ80A | AZ31B | ZK60A |
|---|---|---|---|
| Mg | ~91.3 | 95.0-96.6 | 94 |
| Al | 8.2 | 2.5-3.5 | |
| Zn | 0.38 | 0.7-1.3 | 4.8-6.2 |
| Mn | 0.14 | ≧0.2 | |
| Si | 0.01 | ≦0.05 | |
| Cu | | ≦0.05 | |
| Fe | 0.004 | ≦0.005 | |
| Ni | 0.0007 | ≦0.005 | |
| Zr | | | ≧0.45 |
| Other | <0.03 | ≦0.30 | |

The substrate may have a high aspect ratio. As used herein, aspect ratio refers to the ratio of the cross-sectional dimensions of the substrate in two orthogonal directions. As is known in the art, depositing coatings on high aspect ratio substrates is frequently problematic because of difficulties in achieving uniform coverage. Coating thickness often varies with position on the substrate and uniformity of thickness becomes more difficult to achieve as the aspect ratio of the substrate increases. It is also difficult to maintain the figure of high aspect ratio substrates when applying coatings because internal stresses inherent to many coatings impart deforming forces to the substrate that alter figure. The present performance-enhancing coatings can be applied with high thickness uniformity to substrates having low or high aspect ratio and can be finished to counteract deforming forces introduced by the coating to restore figure. The substrate may have an aspect ratio of at least 1:1, or at least 2:1, or at least 5:1, or at least 10:1, or at least 20:1.

The optical element includes a performance-enhancing coating on the substrate. The performance-enhancing coating may be a layer of a single material or a multilayer stack of two or more materials. The performance-enhancing coating provides resistance to corrosion and is amenable to finishing processes that provide a low roughness surface and excellent figure. The performance-enhancing coating may include Al or an alloy of Al. Alloys of Al may be advantageous to modify the mechanical/chemical characteristics to aid manufacturing. Pure Al is a relatively soft material and may be difficult to manufacture. In certain applications, for example, pure aluminum may be too ductile, resulting in burrs. A representative example would be a kinoform optical surface where a sharp peak is required on the diffractive portion. Al may be alloyed with other elements to increase hardness, modify ductility, and improve machining characteristics to provide better optical geometry or a wider range of shapes. Elements that may be alloyed with Al include one or more of: antimony, bismuth, boron, calcium, carbon, chromium, cobalt, copper, gallium, indium, iron, lead, lithium, magnesium, nickel, niobium, phosphorous, silicon, vanadium, zinc, and zirconium. The composition of the Al alloy can also be adjusted to provide good CTE match with the underlying substrate. In one embodiment, the performance-enhancing coating differs in composition from the substrate and lacks intermetallic particles.

The thickness of the performance-enhancing coating is preferably large enough to permit finishing by a diamond turning process. The performance-enhancing coating has a thickness of at least 30 μm, or at least 40 μm, or at least 50 μm, or at least 100 μm, or at least 125 μm, or at least 150 μm, or in the range from 30 μm to 400 μm, or in the range from 40 μm to 300 μm, or in the range from 50 μm to 250 μm. Thicknesses of at least 30-40 μm are sufficiently large to permit diamond turning of flat surfaces. Powered (curved) surfaces require thicker coatings (e.g. at least 100 μm) to permit diamond turning.

The optical element may include a performance-enhancing coating having two or more layers, where each layer consists of a performance-enhancing material. The two or more layers of performance-enhancing materials may be different materials or the same material and may be in direct or indirect contact. In one embodiment, the two or more layers of performance-enhancing materials are separated by an intervening oxide layer. The intervening oxide layer may be a layer of Al₂O₃. Inclusion of one or more Al₂O₃ layers may improve the smoothness of the layers of the performance-enhancing materials. When intervening oxide layers are present in the performance-enhancing coating, the top layer of the coating remains a layer of performance-enhancing material having a thickness of at least 30 μm as described hereinabove to insure that the performance-enhancing coating is thick enough to permit finishing by a diamond turning process. Underlying layers of performance-enhancing materials may be less than 30 μm thick.

To insure stability of performance over a wide temperature range, the performance-enhancing coating and substrate preferably have similar coefficients of thermal expansion. In one embodiment, the coefficient of thermal expansion of the performance-enhancing coating is no more than 5% greater than and no less than 5% less than the coefficient of thermal expansion of the substrate. Stated alternatively, the coefficient of thermal expansion of the performance-enhancing coating equals the coefficient of thermal expansion of the substrate ±5%.

In one embodiment, the performance-enhancing coating is in direct contact with the substrate. In another embodiment, the optical element includes an interface layer between the performance-enhancing coating and the substrate. The interface layer may promote adhesion between the performance-enhancing coating and substrate. The interface layer may also insure galvanic compatibility between the performance-enhancing coating and substrate. When deployed in humid or salty operating environments, the relative corrosion resistance of the substrate material and the materials used in the coatings and layers of the optical element is an important consideration. For purposes of electrochemical activity, the materials included in the optical element can be characterized by an anodic index. As is known in the art, corrosion between consecutive layers in a stack of layers becomes problematic if the anodic index difference between the consecutive layers exceeds a certain threshold. The threshold depends on the particular conditions of the operating environment, but is typically in the range from 0.10 V to 0.50 V. If the deployment environment of the optical element exposes it to salt (e.g. salt fog), the anodic index difference should not exceed 0.25 V. If salts are absent from the deployment environment, a higher anodic index difference between consecutive layers can be tolerated.

Materials with a difference in anodic index at or below the threshold are said to have galvanic compatibility. Maintaining galvanic compatibility of consecutive layers in a stack (sequence of layers) minimizes the effects of corrosion. If the difference in anodic index of the performance-enhancing coating and substrate exceeds the threshold for galvanic compatibility, it is desirable to include an interface layer between the performance-enhancing coating and the substrate. The interface layer should have an anodic index intermediate between the anodic indices of the substrate and performance-enhancing coating. If the difference in anodic index between the substrate and performance-enhancing coating is large, a series of two or more interface layers may be included to insure galvanic compatibility. Materials for the interface layers can be selected to provide a stepwise change in anodic index to insure galvanic compatibility of all adjacent layers in the sequence of layers needed to bridge the difference in anodic index of the substrate and performance-enhancing coating.

In one embodiment, the performance-enhancing coating is in direct contact with the substrate and the difference between the anodic index of the performance-enhancing coating and the anodic index of the substrate is less than 0.50 V, or less than 0.40 V, or less than 0.30 V, or less than 0.20 V, or less than 0.10 V.

In one embodiment, the interface layer is in direct contact with the substrate and in direct contact with the performance-enhancing coating and the difference between the anodic index of the interface layer and the anodic index of the substrate is less than 0.50 V, or less than 0.40 V, or less than 0.30 V, or less than 0.20 V, or less than 0.10 V. In one embodiment, the interface layer is in direct contact with the substrate and in direct contact with the performance-enhancing coating and the difference between the anodic index of the interface layer and the anodic index of the performance-enhancing coating is less than 0.50 V, or less than 0.40 V, or less than 0.30 V, or less than 0.20 V, or less than 0.10 V.

Representative interface layers include one or more of Ni, Cr, NiCr, Ti, TiO₂, ZnS, Ni, Pt, Ta₂O₅, Nb₂O₅, Al₂O₃, AIN, AlOₓN_{y}, Bi, Bi₂O₃. Si₃N₄, SiO₂, SiOₓN_{y}, DLC (diamond-like carbon), MgF₂, YbF₃, and YF₃. An interface layer may both promote adhesion and provide galvanic compatibility between the substrate and the performance-enhancing coating. In one embodiment, the substrate includes Mg or an alloy of Mg, the performance-enhancing coating includes Al or an alloy of Al, and the optical element includes an interface layer between the substrate and performance-enhancing coating, where the interface layer includes a dielectric fluoride compound such as MgF₂, YbF₃, or YF₃.

The optical element may optionally include a reflective coating on the performance-enhancing coating. The reflective coating preferably provides high reflectivity in one or more of the visible (VIS), near infrared (NIR), shortwave infrared (SWIR), midwave infrared (MWIR), and long wave infrared (LWIR) bands. The reflective coating may be a layer of a single material or a multilayer stack of two or more materials. In one embodiment, the reflective coating includes a reflective layer and one or more tuning layers. The reflective coating may optionally include a barrier layer, one or more interface layers, and one or more protective layers.

The protective layer provides resistance to scratches, resistance to mechanical damage, and chemical durability. Representative materials for the protective layer include YbF₃, YbFₓO_{y}, YF₃ and Si₃N₄. The protective layer(s) is the top layer of the reflective coating. The protective layer(s) may have a thickness in the range of 60 nm to 200 nm.

The reflective layer may include a metal layer or a transition metal layer. The reflective layer preferably has high reflectivity at wavelengths in the VIS, NIR, SWIR, MWIR, and LWIR spectral bands. The reflective metal may be metallic, non-ionic, a pure metal or metal alloy, and/or zero valent. The reflective layer may include one or more elements selected from the group consisting of Ag, Au, Al, Rh, Cu, Pt and Ni. The thickness of the reflective transition metal layer may be in the range from 75 nm to 350 nm, or in the range from 80 nm to 150 nm, or in the range from 90 nm to 120 nm.

The reflective coating may include one or more tuning layers. The one or more tuning layers are positioned between the protective layer(s) of the reflective coating and the performance-enhancing coating. In one embodiment, the tuning layer(s) are positioned between the reflective layer and the protective layer(s) of the reflective coating. Tuning layer(s) are designed to optimize reflection in defined wavelength regions. Tuning layer(s) typically include an alternating combination of high and low refractive index materials, or high, intermediate, and low refractive index materials. Materials used for tuning layers are preferably low absorbing in the wavelength range of from 0.4 μm to 15.0 μm. Representative materials for tuning layers include YbF₃, GdF₃, YF₃, YbOₓF_{y}, GdF₃, Nb₂O₅, Bi₂O₃, and ZnS. The tuning layer(s) may have a thickness in the range of 75 nm to 300 nm. In one embodiment, the reflective coating includes YbF₃ and ZnS as tuning layers.

The reflective layer and tuning layer(s) may be in direct contact or one or more interface layers may be present between the reflective layer and tuning layer(s). The interface layer(s) may promote adhesion or provide galvanic compatibility between the reflective layer and tuning layer(s). The interface layer(s) needs to have a thickness sufficient for adhesion, but must also be thin enough to minimize absorption of light reflected from the reflective layer. The interface layer(s) positioned between the reflective layer and the tuning layer(s) may have a thickness in the range of 5 nm to 20 nm, or 8 nm to 15 nm, or 8 nm to 12 nm. The interface layer(s) positioned between the reflective layer and the tuning layer(s) may include one or more of Nb₂O₅, TiO₂, Ta₂O₅, Bi₂O₃, ZnS and Al₂O₃.

In one embodiment, the reflective layer is in direct contact with the performance-enhancing coating. In another embodiment, the optical element includes a barrier layer and/or an interface layer between the reflective layer and the performance-enhancing coating. In still another embodiment, the optical element includes a barrier layer in direct contact with the performance-enhancing coating. In yet another embodiment, the optical element includes a barrier layer in direct contact with the performance-enhancing coating and an interface layer in direct contact with the barrier layer. The interface layer may promote adhesion between the reflective layer and barrier layer, or between the reflective layer and the corrosion protection layer. The interface layer may also insure galvanic compatibility of the reflective coating with the performance-enhancing coating, or galvanic compatibility of the barrier layer with the reflective layer. The barrier layer may insure galvanic compatibility between the reflective layer and the substrate.

Representative barrier layers include Si₃N₄, SiO₂, TiAlN, TiAlSiN, TiO₂, DLC (diamond-like carbon), Al, CrN, and SiₓN_{y}O_{z}. The barrier layer may have a thickness in the range from 100 nm to 50 μm, or in the range from 500 nm to 10 μm, or in the range from 1 μm to 5 μm. One criterion for determining the thickness of the barrier is the number of hours the article will have to withstand the salt fog test. The longer the duration of the salt fog test, the greater the required thickness of the barrier layer. For a salt fog test of 24 hours, a barrier layer of 10 μm has been found sufficient. The thickness of the barrier layer can also be adjusted to accommodate changes in temperature without distorting the figure of the optical element. Thermal stresses increase as the operational temperature range increases, so thinner barrier layers are recommended to avoid figure distortion in deployment environments experiencing large swings in temperature.

Representative interface layers positioned between the performance-enhancing coating and the reflective layer include one or more of Ni, Cr, Ni—Cr alloys (e.g. Nichrome), Ni—Cu alloys (e.g. Monel), Ti, TiO₂, ZnS, Pt, Ta₂O₅, Nb₂O₅, Al₂O₃, AlN, AlOₓN_{y}, Bi, Bi₂O₃. Si₃N₄, SiO₂, SiOₓN_{y}, DLC (diamond-like carbon), MgF₂, YbF₃, and YF₃. The interface layer may have a thickness in the range from 0.2 nm to 25 nm, where the lower end of the thickness range (e.g. 0.2 nm to 2.5 nm, or 0.2 nm to 5 nm) is appropriate when the interface layer is a metal (to prevent parasitic absorbance of light passing through the reflective coating) and the higher end of the thickness range (e.g. 2.5 nm to 25 nm, or 5 nm to 25 nm) is appropriate when the interface layer is a dielectric.

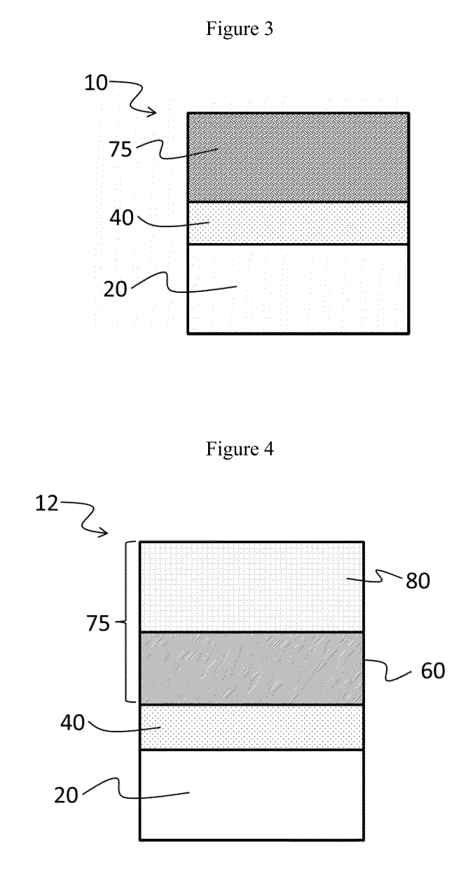

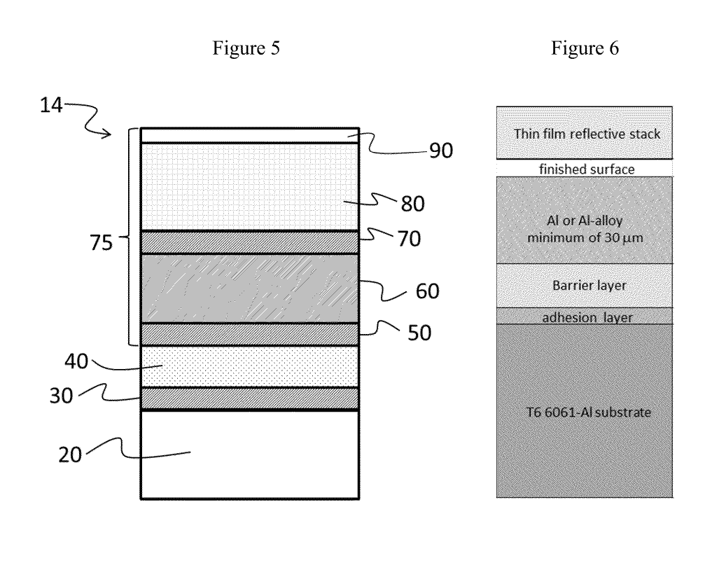

FIG. 3 shows one embodiment of an optical element. Optical element 10 includes substrate 20, performance-enhancing coating 40, and reflective coating 75. FIG. 4 shows another embodiment of an optical element. Optical element 12 includes substrate 20, performance-enhancing coating 40, and reflective coating 75, where reflective coating 75 includes reflective metal layer 60 and one or more tuning layers 80. FIG. 5 shows still another embodiment of an optical element. Optical element 14 includes substrate 20, performance-enhancing coating 40, and reflective coating 75 with reflective metal layer 60, tuning layer(s) 80, interface layers 50 and 70, and protective layer 90. Optical element 14 further includes interface layer 30 between substrate 20 and performance-enhancing coating 40. Any or all layers 30, 50, 70, 75, and 90 are optional. The optical element may include no interface layers, or one or more interface layers, or two or more interface layers, or three or more interface layers. When two or more interface layers are present, they may have the same or different composition.

FIG. 6 shows an embodiment that includes an adhesion layer and a barrier layer between the substrate and the performance-enhancing coating. In FIG. 6, the substrate is T6 6061-Al and the performance-enhancing coating is Al or Al-alloy having a minimum thickness of 30 μm to insure amenability to finishing via a diamond turning process. The finished surface is indicated for purposes of illustration and the reflective coating, identified as a thin film reflective stack, is in direct contact with the finished surface.

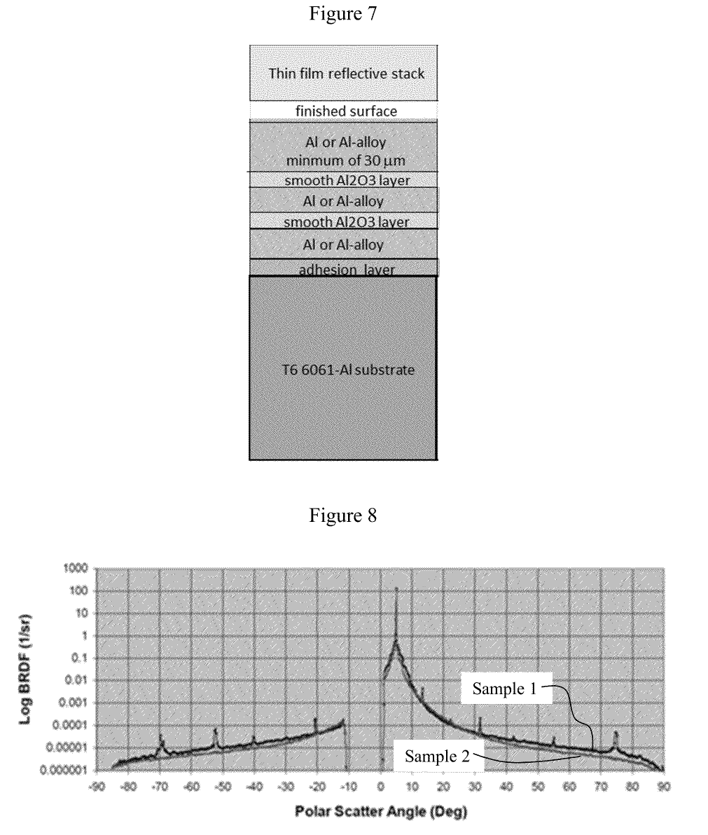

FIG. 7 shows an embodiment in which the performance-enhancing coating includes intervening layers of Al₂O₃. In FIG. 7, the substrate is T6 6061-Al and the optical element includes an adhesion layer between the performance-enhancing coating and the substrate. Al or Al-alloy is the corrosion protection material and is present in three layers of the performance-enhancing coating, where the top layer of corrosion protection material has a thickness of at least 30 μm to insure amenability to finishing via a diamond turning process. The finished surface is indicated for purposes of illustration and the reflective coating, identified as a thin film reflective stack, is in direct contact with the finished surface.

Fabrication of the optical element includes forming a performance-enhancing coating on a substrate, forming a reflective coating on the performance-enhancing coating, and optionally forming interface layer(s), barrier layer(s), and protective layer(s).

Fabrication of the optical element may also include treatment of the substrate surface before depositing a material thereon. Treatment of the substrate surface may clean the substrate surface, remove defects or impurities, and/or smooth the substrate surface. Treatment of the substrate surface may include heating the substrate surface, polishing the substrate surface, exposing the substrate surface to a plasma or an ion beam, or diamond turning. In one embodiment, treatment of the substrate surface includes heating for 1-2 hours at 80-110° C. In another embodiment, treatment of the substrate surface includes ion bombardment for 15-30 minutes. Heating and ion bombardment may occur after diamond turning the substrate. Polishing may occur after diamond turning the substrate and before heating or ion bombardment of the substrate.

Treatment of the substrate surface reduces the roughness of the surface and produces a flatter surface. The RMS (root-mean-square) roughness of the treated substrate surface may be less than 60 Å, or less than 50 Å, or less than 40 Å. The RMS flatness of the treated substrate surface may be less than 0.05 waves RMS, or less than 0.04 waves RMS, or less than 0.03 waves RMS, or less than 0.02 waves RMS. As used herein, flatness refers to the smoothness of a surface as determined by an interferometer that uses light having a wavelength of 632.8 nm to interrogate the surface. In the interferometric analysis of the surface, flatness is assessed by counting interference fringes. Two fringes correspond to a wavelength of the interrogating light and define the dimension “waves” used herein to characterize the flatness of a surface.

The performance-enhancing coating may be formed on a treated or untreated surface of the substrate. The performance-enhancing coating, barrier layer(s), interface layer(s), reflective layer(s), tuning layer(s), and protective layer(s) may be deposited by sputtering, physical vapor deposition, evaporation, plasma ion assisted deposition, or chemical vapor deposition. An exemplary low pressure magnetron sputtering process is described in U.S. Pat. No. 5,525,199, the disclosure of which is incorporated by reference herein. Chamber “over” pumping along with source and gas tooling configurations enable the low pressure sputtering, and allow the deposition of dense reactive and non-reactive films. Co-sputtering, for example of Mg and Al, or sputtering from an aluminum alloyed target of defined composition, can be used to enhance CTE matching with Al or Al-alloy substrates. The low pressure magnetron sputtering process can also be used to form of nitride, oxide, or oxynitride compounds of Al and other elements to provide interface and/or barrier layers. The density of the film can be influenced through deposition rate, ion bombardment of the surface, or exposure of the surface to a plasma. Slow deposition rates provide denser, more defect-free layers. The deposition rate of the performance-enhancing coating may be less than 10 Å/sec, or less than 5 Å/sec, or less than 2 Å/sec. In-situ smoothing of the aluminum or aluminum alloy coating is achievable through ion bombardment or exposure to a plasma. Argon ion bombardment of the surface is used pre-coating deposition, and in some cases an adhesion layer of Ni, Cr, NiCr, Ti, Al₂O₃, Bi or Bi₂O₃ may be used to improve the bonding at the substrate/coating interface. Surface preparation is critical to obtaining the proper adhesion, and care and attention should be given to removing residual processing contaminants.

Once a specific composition for the performance-enhancing coating has been identified, a sputtering target of the defined composition is fabricated and used to sputter the desired coating. Since the substrate surface influences the morphology of the coating, it is preferable to treat the substrate surface as described hereinabove to make it is as smooth and defect-free as possible. Thin films with characteristically smooth surface morphology, for example Al₂O₃, can be inserted into the stack of layers during deposition. Such layers, however, need to remain below the depth of material expected to be removed in post-deposition finishing steps. High angle ion bombardment at the substrate surface can also be used to optimize morphology.

The performance-enhancing coating, barrier layer, interface layer(s), reflective layer(s), tuning layer(s), and/or protective layer(s) may optionally be densified during deposition to minimize defects. Densification techniques include ion or plasma bombardment during deposition, minimization of high angle deposition from the sputtering target (e.g. via source masking), or inclusion of one or more densification layers in the stack of layers formed on the substrate. The densification technique may also smoothen the layers. Ion or plasma bombardment may utilize ions or plasmas formed from an inert gas (e.g. Ar, Kr, He). In one embodiment, ion bombardment of the surface during deposition utilizes an average Ar ion beam density of 0.5 to 1 mA/cm² and average Ar ion energy of 30 eV to 60 eV.

After deposition, the surface of the performance-enhancing coating may be finished to reduce roughness. Finishing may include diamond turning and/or polishing. The thickness of the performance-enhancing coating is designed to be large enough to permit diamond turning of the performance-enhancing coating without damaging the surface of the substrate. The finished surface of the performance-enhancing coating may have an RMS roughness less than 50 Å, or less than 40 Å, or less than 30 Å, or less than 20 Å, or less than 15 Å, or less than 10 Å. The peak-to-valley (PV) roughness of the finished surface of the performance-enhancing coating may be less than 50 nm, or less than 40 nm, or less than 30 nm, or in the range from 10-50 nm, or in the range from 10-40 nm, or in the range from 10-30 nm. The RMS flatness of the finished surface of the performance-enhancing coating may be less than 0.05 waves RMS, or less than 0.04 waves RMS, or less than 0.03 waves RMS, or less than 0.02 waves RMS. The peak-to-valley (PV) figure of the finished surface of the performance-enhancing coating may be less than 0.40 waves, or less than 0.30 waves, or less than 0.20 waves.

Polishing of the substrate or performance-enhancing coating may include applying a polishing formulation that includes a colloidal silica medium. The colloidal silica medium may be a solution or suspension of colloidal silica in a liquid. The colloidal silica may have an average particle size in the range from 0.01 μm-0.10 μm, or in the range from 0.01 μm to 0.05 μm, or in the range from 0.01 μm-0.03 μm, or in the range from 0.02 μm-0.05 μm. The liquid component of the colloidal silica medium may include an alcohol. The alcohol may be a diol or glycol, such as ethylene glycol or propylene glycol. The liquid medium may further include water. In one embodiment, the colloidal silica medium includes 25 wt %-50 wt % colloidal silica, 5 wt %-50 wt % alcohol, and 25 wt %-65 wt % water. In one embodiment, the colloidal silica medium includes 30 wt %-45 wt % colloidal silica, 5 wt %-40 wt % alcohol, and 20 wt %-60 wt % water. In one embodiment, the polishing formulation includes 35 wt %-40 wt % colloidal silica, 10 wt %-35 wt % alcohol, and 25 wt %-55 wt % water. Representative colloidal silica media include Product Nos. 180-40015, 180-40010, 180-40000, 180-20015, 180-20010, and 180-20000 from Allied High Tech Products Inc. (Rancho Dominguez, Calif.)

The polishing formulation may further include an alumina suspension. The alumina suspension includes colloidal alumina in a suspension medium. The colloidal alumina may have an average particle size in the range from 0.01 μm-0.10 μm, or in the range from 0.02 μm to 0.08 μm, or in the range from 0.03 μm-0.06 μm. The suspension medium of the alumina suspension may include an alcohol. The alcohol may be a diol or glycol, such as ethylene glycol or propylene glycol. The alumina suspension may also include colloidal silica. The colloidal silica may have an average particle size in the range from 0.01 μm-0.10 μm, or in the range from 0.01 μm to 0.05 μm, or in the range from 0.01 μm-0.03 μm, or in the range from 0.02 μm-0.05 μm. In one embodiment, the alumina suspension includes 1 wt %-30 wt % colloidal alumina, 1 wt %-30 wt % colloidal silica, and 5 wt %-40 wt % alcohol. In another embodiment, the alumina suspension includes 5 wt %-25 wt % colloidal alumina, 5 wt %-25 wt % colloidal silica, and 10 wt %-35 wt % alcohol. In still another embodiment, the alumina suspension includes 5 wt %-20 wt % colloidal alumina, 5 wt %-20 wt % colloidal silica, and 10 wt %-30 wt % alcohol. Representative alumina suspensions include Product Nos. 4010084, 406377032, and 406380064 available from Buehler (Lake Bluff, Ill.).

The polishing formulation may optionally include a surfactant (e.g. 7× Microsoap (available from MP Biomedicals (Santa Ana, Calif.).

The composition and relative proportions of the components of the polishing formulation may be adjusted to control the pH of the polishing formulation. The polishing formulation may have a pH of at least 8.0, or at least 8.5, or between 8.0 and 10.0, or between 8.5 and 9.5, or between 8.75 and 9.25. Polishing with the polishing formulation is both chemical and mechanical in nature. Control of the pH to provide mildly basic conditions facilitates chemical dissolution of surface oxides, including aluminum oxides that may form on the substrate surface and/or surface of the performance-enhancing coating.

In one embodiment, the polishing formulation includes 60 wt %-90 wt % colloidal silica medium, 5 wt %-30 wt % alumina suspension, and 0-5 wt % detergent. In another embodiment, the polishing formulation includes 70 wt %-85 wt % colloidal silica medium, 10 wt %-25 wt % alumina suspension, and 0-5 wt % detergent. In still another embodiment, the polishing formulation includes 75 wt %-80 wt % colloidal silica medium, 15 wt %-20 wt % alumina suspension, and 0-5 wt % detergent.

In one embodiment, the polishing formulation lacks alumina suspension and includes at least 90 wt % colloidal silica medium and 0-5 wt % detergent. In another embodiment, the polishing formulation lacks alumina suspension and includes at least 95 wt % colloidal silica medium and 0-5 wt % detergent.

The polishing formulation may be applied to a polishing pad, which may be designed to be conformal to the surface of the substrate or performance-enhancing coating. The polishing pad may be constructed from silk, pitch, wax, resin, Politex™, felt polyurethane, and/or other pad materials known in the art. Other polishing techniques include deterministic polishing methods, including magnetorheological finishing and ion beam milling. The thickness of the performance-enhancing coating is sufficient to permit deterministic polishing, even after diamond turning, without exposing the surface of the underlying substrate or, if present, underlying interface layer. Polishing may remove oxides that form on the surfaces of the substrate or performance-enhancing coating. As is known in the art, diamond turning may produce periodic structures on a surface. Polishing may remove periodic structures produced by diamond turning.

When the reflective coating is in direct contact with the performance-enhancing coating, it may be formed on an unfinished or finished surface of the performance-enhancing coating.

In one aspect, the present description is directed to a method for forming optical elements to improve the corrosion resistance and durability thereof, the method comprising providing a substrate selected from the group consisting of metal and metal alloy substrates; diamond turning the substrate to a surface roughness in the range of 60-100 Å; polishing the surface of the diamond-turned substrate to a roughness in the range of 10-25 Å; heating the substrate to a temperature in the range of 80° C. to 110° C. for a time in the range of 1-2 hours; ion bombarding the substrate with an inert gas for a time in the range 15-30 minutes; depositing one or more layers of a performance-enhancing material on the surface of the ion-bombarded substrate using low pressure magnetron sputtering to thereby form a performance-enhancing coating having a thickness of at least 30 μm; diamond turning the performance-enhancing coating; and polishing the performance-enhancing coating using a glycol-based colloidal silica medium having a pH in the range of 8.9 to 9.2 to thereby form a diamond-turned surface of the performance-enhancing coating having a surface roughness of less than 25 Å RMS.

In another aspect, the method includes depositing an adhesion layer having a thickness in the range of 5 nm to 50 nm on top of the substrate; depositing a first layer of performance-enhancing material on top of the adhesion layer; depositing a first Al₂O₃ layer having a thickness or 100 nm or more on top of the first layer of performance-enhancing material; depositing a second layer of performance-enhancing material on top of the first Al₂O₃ layer; depositing a second Al₂O₃ layer having a thickness of 100 nm or more on top of the second layer of performance-enhancing material; and depositing a third layer of performance-enhancing material on top of the second Al₂O₃ layer.

In one embodiment, the optical element in accordance with the present description has a reflectivity of at least 94% over the wavelength range of 400 nm to 1700 nm. In another embodiment, the optical element has a reflectivity of at least 96% over the wavelength range of 800 nm to 1700 nm.

### EXAMPLES

The following examples are illustrative of the benefits offered by the optical elements and methods of fabrication thereof described herein. The examples are not intended to limit the scope of the present description or claims.

FIG. 8 shows the bidirectional reflective distribution function (BDRF) of T6 6061-Al substrate material. The bidirectional reflective distribution function is a measure of the smoothness of a surface. The bidirectional reflective distribution functions of two samples of T6 6061-Al substrate material are shown in FIG. 8. Sample 1 is a T6 6061-Al sample having a surface that was diamond-turned. Sample 2 is a T6 6061-Al sample having a surface that was diamond turned and then polished with a polishing formulation that included of colloidal silica in glycol (Product No. 180-40000 from Allied High Tech Products, Inc.). The BDRF for Sample 1 shows a broad background and a series of sharp peaks. The sharp peaks are attributable to periodic structures that form in the surface of the substrate material during the diamond turning process. The production of periodic surface features is a known consequence of diamond turning. The broad background intensity is attributable to scattering from non-periodic roughness on the surface of the substrate. In the BDRF for Sample 2, the periodic features are absent and the background intensity is diminished. The results indicate that polishing a diamond-turned surface of a substrate with a polishing formulation that includes colloidal silica in glycol removes periodic surface features produced by the diamond turning process and reduces the overall roughness of the surface.

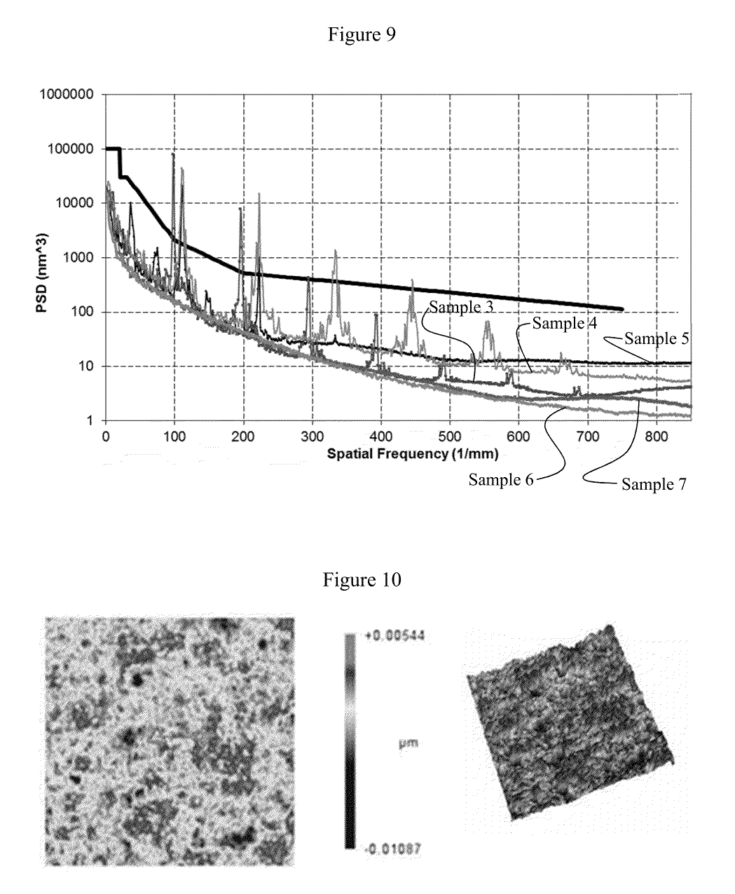

FIG. 9 shows the power spectral density (PSD) curves of several samples of T6 6061-Al substrate material. The power spectral density curve is a measure of RMS roughness of a surface. More specifically, RMS surface roughness is proportional to the square root of the area under the power spectral density curve. Power spectral density curves for five samples are shown in FIG. 9. The samples had dimensions of 1″×1″. Samples 3, 4, and 5 correspond to T6 6061-Al substrate material with diamond-turned surfaces that were not polished and that did not include a performance-enhancing coating. Samples 6 and 7 correspond to T6 6061-Al substrate material with diamond-turned surfaces that were polished with a glycol-based colloidal silicon medium and coated with a layer of Al having a thickness sufficient to permit diamond turning. The layer of Al constitutes a performance-enhancing coating and was formed by low pressure magnetron sputtering using an Al metal target. After deposition, the Al coating was diamond turned and polished with a glycol-based colloidal silicon medium. The unlabeled curve in FIG. 9 is an instrumental response function and does not correspond to a sample.

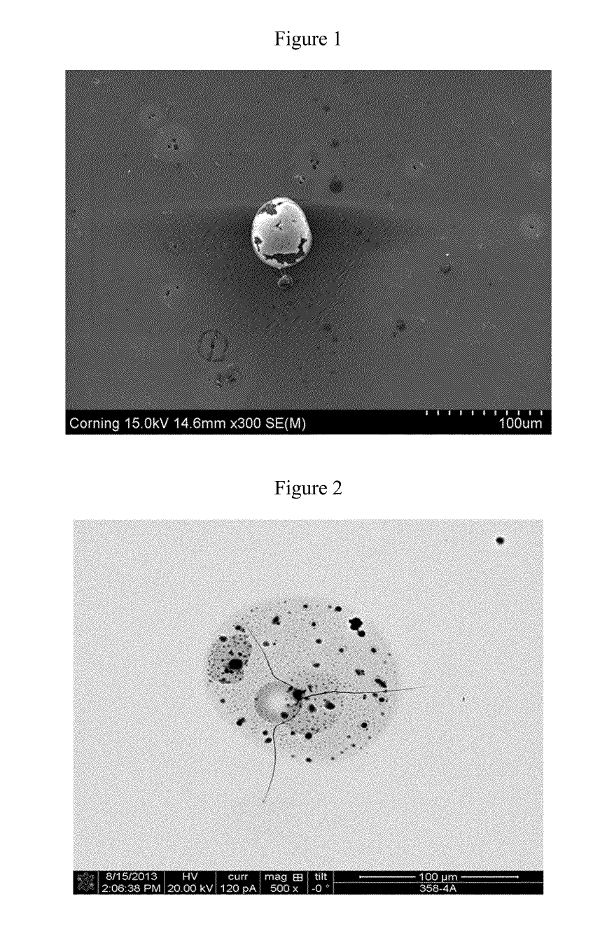

The structured peaks observed in the PSD curves of Samples 3-5 correspond to periodic surface features produced by the diamond turning process. Samples 3-5 are typical of substrate materials currently used to form optical elements. The high surface roughness of the substrate leads to increased roughness for reflective coatings formed on the substrate and the lack of a performance-enhancing coating facilitates corrosion and failure of the type shown in FIGS. 1 and 2. Although, as noted hereinabove, polishing can remove periodic structures from T6 6061-Al substrate, the overall roughness remains high because of the presence of intermetallic particles that limit the smoothness of finish available from polishing.

The periodic features are absent in Samples 6 and 7 and the intensity of the background scattering intensity is considerably lower than is observed for Samples 3-5. The PSD results indicate that much smoother surfaces are available for reflective coatings when a performance-enhancing coating is included on the substrate. The Al performance-enhancing coating included in Samples 6 and 7 lacks the intermetallic particles present in T6 6061-Al and can therefore be polished to a lower (smoother, lower roughness) finish.

FIG. 10 shows a secondary electron microscope image of a surface of an Al corrosion protection layer on a 1″×1″ T6 6061-Al substrate (left figure) and a 3D model of the surface obtained from the image (right figure). Analysis of the image indicates that RMS surface roughness is 15.3 Å and peak-to-valley roughness is 163.1 Å. The quality of the surface of the performance-enhancing coating is far superior to that of a standard T6 6061-Al substrate. Reflective coatings formed on the surface of the performance-enhancing coating will accordingly have smoother surfaces and since the surface of the performance-enhancing coating is not nearly as susceptible to corrosion as standard T6 6061-Al substrates, reflective coatings formed on the surface of the performance-enhancing coating will be far less prone to cracking and other damage associated with corrosion.

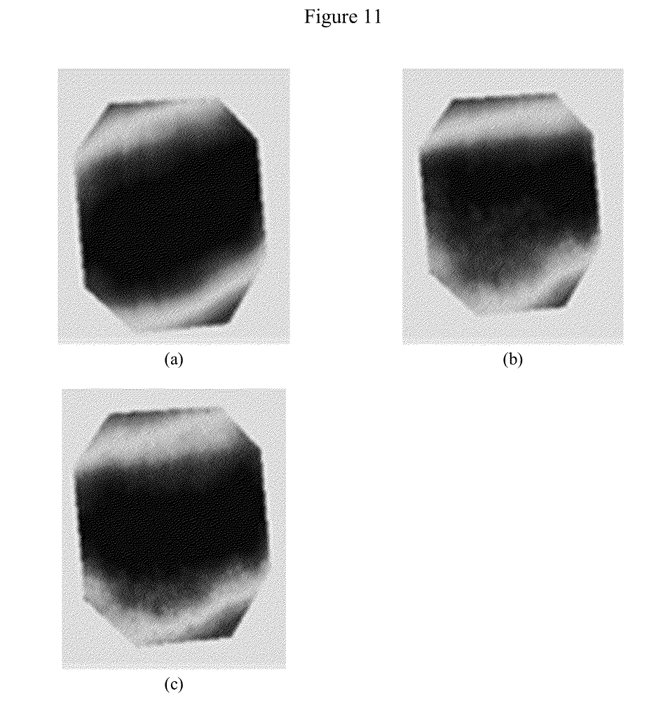

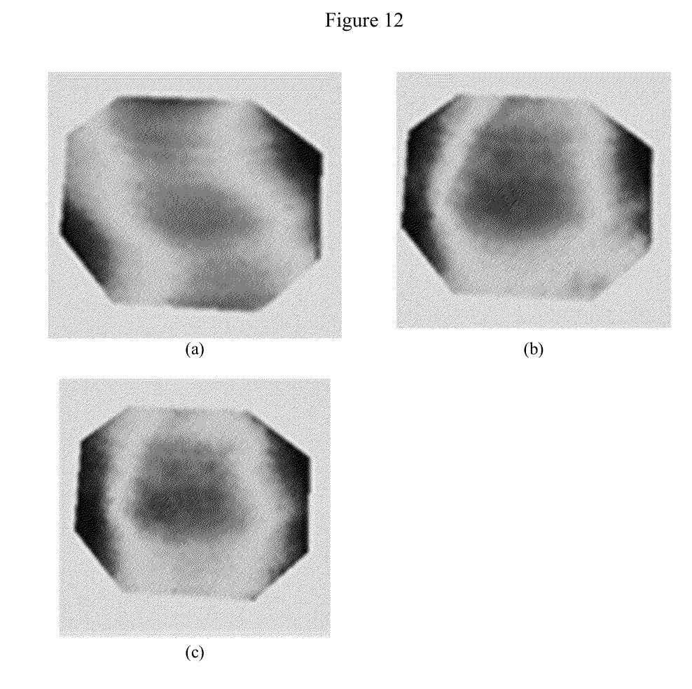

FIG. 11 depicts the figure of an optical element that includes T6061 Al substrate and a performance-enhancing coating. The performance-enhancing coating was Al and was finished with diamond turning. Figure of the element is shown at different points in a temperature cycle. Panel (a) shows figure of the element at ambient temperature outside of a vacuum chamber. Peak-to-valley (PV) figure was measured to be 0.243 waves and RMS figure was measured to be 0.045 waves. Panel (b) shows figure of the element upon cooling to −70° C. under vacuum. Peak-to-valley (PV) figure was measured to be 0.259 waves and RMS figure was measured to be 0.052 waves. Panel (c) shows figure of the element under vacuum upon return of the temperature to ambient temperature. Peak-to-valley (PV) figure was measured to be 0.253 waves and RMS figure was measured to be 0.047 waves. The element was cooled back to −70° C. under vacuum and returned to ambient temperature under vacuum in a second thermal cycle. The RMS figure was measured to be 0.043 waves at −70° C. and 0.046 waves at ambient temperature in the second thermal cycle.

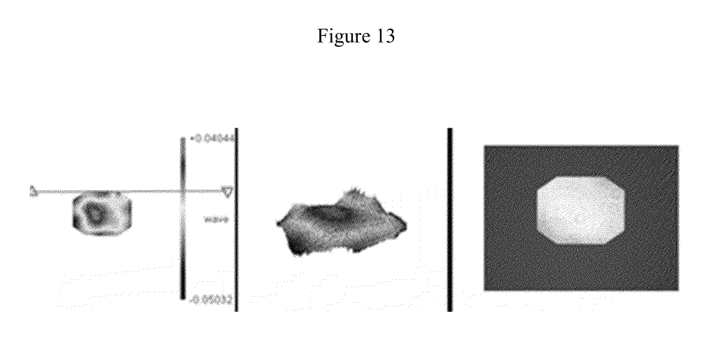

For comparison, FIG. 12 depicts the figure of the base T6061 Al substrate without a performance-enhancing coating. The surface of the substrate was diamond turned. Panel (a) shows figure of the element at ambient temperature outside of a vacuum chamber. Peak-to-valley (PV) figure was measured to be 0.247 waves and RMS figure was measured to be 0.037 waves. Panel (b) shows figure of the element upon cooling to −70° C. under vacuum. Peak-to-valley (PV) figure was measured to be 0.250 waves and RMS figure was measured to be 0.047 waves. Panel (c) shows figure of the element under vacuum upon return of the temperature to ambient temperature. Peak-to-valley (PV) figure was measured to be 0.233 waves and RMS figure was measured to be 0.045 waves. The substrate was cooled back to −70° C. under vacuum and returned to ambient temperature under vacuum in a second thermal cycle. The RMS figure was measured to be 0.042 waves at −70° C. and 0.044 waves at ambient temperature in the second thermal cycle.

The results of FIGS. 11 and 12 demonstrate the excellent match in the coefficient of thermal expansion of the performance-enhancing coating and the base substrate. The thermal characteristics of the performance-enhancing coating closely match those of the base substrate to temperatures at least as low as −70° C.

FIG. 13 shows an analysis of the flatness of the surface of a high aspect ratio T6061 Al substrate with a performance-enhancing coating. The aspect ratio of the substrate was 25:1 and the performance-enhancing coating was Al. The surface of the performance-enhancing coating was diamond turned. The data indicate that the flatness of the surface of the performance-enhancing coating was 0.02±0.003 waves RMS.

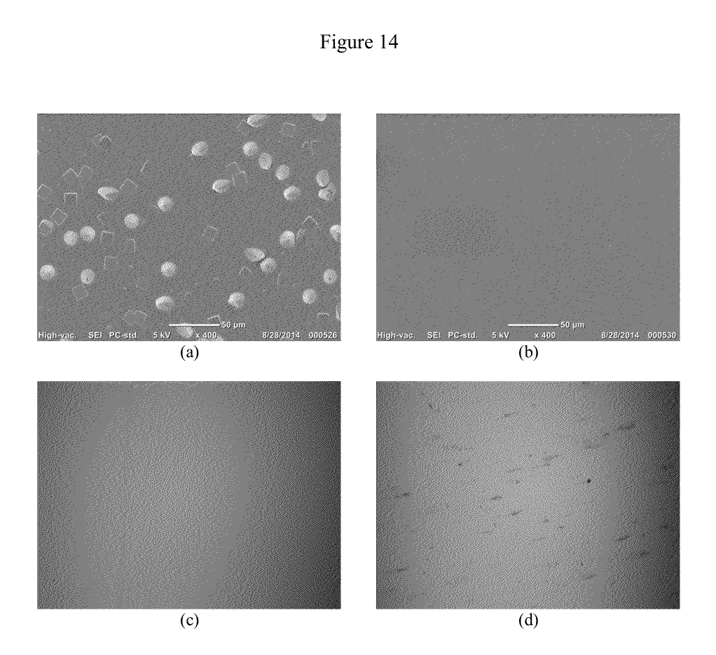

FIG. 14 shows SEM images (400×) for various samples at different stages of fabrication. Panel (a) shows the surface of an optical element that includes a substrate (T6061 Al) and a performance-enhancing coating (Al). The surface corresponds to the surface of the performance-enhancing coating after deposition without smoothing and without diamond turning. The roughness of the surface is high and particulate matter is observed on the surface. Panel (b) shows the surface of the performance-enhancing coating after smoothing and before diamond turning. The smoothing process leads to a marked improvement in the quality of the surface. Panel (c) shows the surface of the smoothed performance-enhancing coating after diamond turning. The roughness of the surface was measured to be 25 Å RMS. Panel (d) shows an image of a comparative diamond-turned surface for the T6061 Al substrate without a performance-enhancing coating. The roughness of the surface was measured to be 75 Å RMS. The data illustrate that much lower surface finish achievable when the optical element includes a performance-enhancing coating.

A performance-enhancing coating (Al) was applied to three Al substrate samples produced by the DMLS (direct metal laser sintering) process. DMLS is an additive metal fabrication method that readily produces complex lightweight geometries in a reasonable time. The DMLS samples were produced on an EOS 280 DMLS machine using maximum density settings. The samples had a diameter of two inches, a thickness of 0.37 inch, and a honeycomb light weighting pattern. The samples were annealed, machined to parallelism, and subjected to hot isostatic pressing.

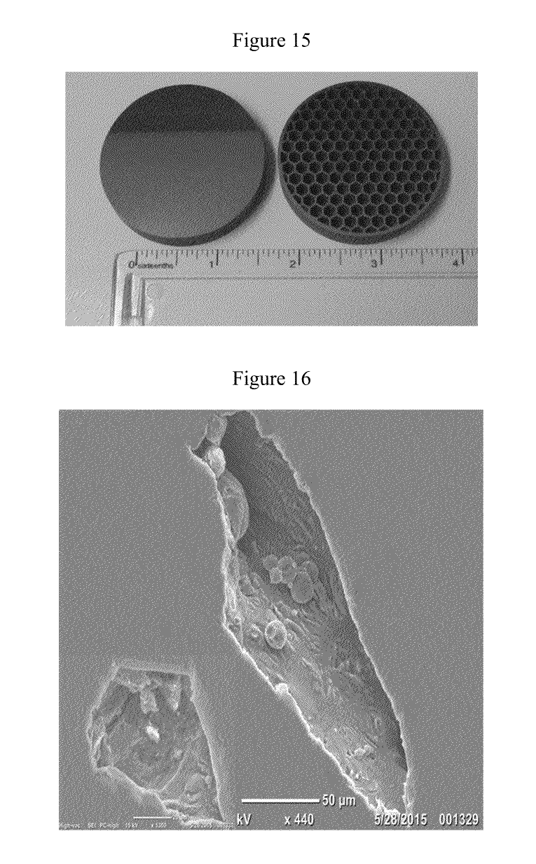

FIG. 15 shows two sides of one sample substrate (Al) produced by the DMLS process. Elemental analysis determined that the DMLS samples included Cr, Si, Ni, and Fe as impurities. Surface analysis of the DMLS samples revealed the presence of large voids and impurity-rich regions (FIG. 16). The voids and impurities led to significant variability in surface finish across the surface of the samples. In one sample, for example, surface finish (rms) varied from 69 Å to 826 Å depending on the location of the measurement. The variability of surface finish was inconsistent among the samples. Each of the three samples was subjected to a diamond turning process. The diamond turning process improved consistency of surface finish among the samples and reduced variability in surface finish across each sample. The average surface finish (rms) of the three samples after diamond turning was 64 Å, 69 Å, and 74 Å, respectively. Polishing after diamond turning led to further improvement in surface finish (e.g. down to an average of 45 Å (rms) and 1043 Å (peak-to-valley) for one sample). Voids, however, remained on the surface and further improvements in surface finish were not possible.

A performance-enhancing coating (Al) was applied to the three samples. The samples were again subjected to diamond turning without additional polishing. Surface characterization revealed smooth surfaces that were free of voids. The average surface finish of one sample was improved to ˜37 Å (rms) and ˜350 Å (peak-to-valley). In the other two samples, average surface finish was improved to ˜16 Å (rms) and ˜190 Å (peak-to-valley). The results indicate a significant improvement in surface finish of substrates prepared by the DMLS process using the methods of the present disclosure.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It will be apparent to those skilled in the art that various modifications and variations can be made without departing from the spirit or scope of the illustrated embodiments. Since modifications, combinations, sub-combinations and variations of the disclosed embodiments that incorporate the spirit and substance of the illustrated embodiments may occur to persons skilled in the art, the description should be construed to include everything within the scope of the appended claims and their equivalents.

We claim:

1. A method for treating a substrate comprising:
providing a substrate, said substrate having a surface coated with a performance-enhancing coating, said performance-enhancing coating differing in composition from said substrate and having a thickness in the range from 40 μm to 300 μm;
finishing a surface of said performance-enhancing coating, said finishing including diamond turning said surface of said performance-enhancing coating and polishing said diamond-turned surface of said performance-enhancing coating, said finishing reducing the RMS (root-mean-square) roughness of said surface of said performance-enhancing coating to less than 40 Å.

2. The method of claim 1, wherein said substrate comprises Al, an alloy of Al, Mg or an alloy of Mg.

3. The method of claim 2, wherein said performance-enhancing coating comprises Al or an alloy of Al.

4. The method of claim 1, wherein said polishing includes applying a formulation to said diamond-turned surface of said performance-enhancing coating, said formulation comprising a colloidal silica medium, said colloidal silica medium comprising colloidal silica and an alcohol.

5. The method of claim 4, wherein said formulation further comprises an alumina suspension, said alumina suspension including colloidal alumina and a suspension medium.

6. The method of claim 4, wherein the pH of said formulation is between 8.0 and 10.0.

7. The method of claim 1, wherein said finishing reduces the RMS (root-mean-square) roughness of said surface of said performance-enhancing coating to less than 20 Å

8. The method of claim 1, further comprising forming said performance-enhancing coating on said surface of said substrate, said forming said performance-enhancing coating including depositing a performance-enhancing material on said surface of said substrate.

9. The method of claim 8, wherein said forming said performance-enhancing coating includes diamond turning said surface of said substrate to a roughness in the range of 60-100 Å RMS, said diamond turning said surface of said substrate occurring before said depositing said performance-enhancing material.

10. The method of claim 1, wherein said surface of said performance-enhancing coating has a peak-to-valley (PV) roughness in the range of 10 nm to 30 nm.

11. The method of claim 8, further comprising forming an adhesion layer on said surface of said substrate, said adhesion layer having a thickness in the range of 5 nm to 50 nm, said performance-enhancing material being deposited on said adhesion layer.

12. The method of claim 11, wherein said substrate comprises Mg, said corrosion protection layer comprises Al, and said adhesion layer comprises Mg.

13. An optical element comprising:
a substrate;
a performance-enhancing coating on a surface of said substrate, said performance-enhancing coating differing in composition from said substrate and having a thickness in the range from 40 μm to 300 μm, said performance-enhancing coating having a surface with an RMS (root-mean-square) roughness of less than 40 Å; and
a reflective coating on said surface of said performance-enhancing coating.

14. The optical element of claim 13, wherein said substrate comprises Al, an alloy of Al, Mg or an alloy of Mg.

15. The optical element of claim 14, wherein said performance-enhancing coating comprises Al or an alloy of Al.

16. The optical element of claim 13, wherein said substrate has a diamond-turned surface.

17. The optical element of claim 16, wherein said surface of said performance-enhancing coating is a diamond-turned surface.

18. The optical element of claim 17, wherein said diamond-turned surface of said performance-enhancing coating has an RMS roughness in the range of 10-25 Å.

19. The optical element of claim 13, further comprising an adhesion layer positioned between said substrate and said performance-enhancing coating, said adhesion layer having a thickness in the range of 5 nm to 50 nm and comprising a material selected from the group consisting of Mg, MgF₂, Ni, Cr, NiCr, Ti, Al₂O₃, Bi or Bi₂O₃.

20. The optical element of claim 13, wherein said reflective coating comprises a material selected from the group consisting of zero valent Ag, Au, Rh, Cu, Pt and Ni, said reflective coating having a thickness in the range of 75 nm to 350 nm.

21. The optical element of claim 13, further comprising a protective layer positioned on said reflective coating, said protective layer comprising a material selected from the group consisting of AlON, SiON, YbF₃, YbFₓO_{y}, YF₃ and Si₃N₄.

22. The optical element of claim 13, wherein said optical element has a reflectivity of at least 96% over the wavelength range of 800 nm to 1700 nm.

23. The optical element of claim 13, wherein said surface of said performance-enhancing coating has an RMS roughness less than 20 Å.
